(19) United States
(12) Patent Application Publication
(10) Pub. No.: US 2014/0233320 A1
(43) Pub. Date: Aug. 21, 2014

(54) NONVOLATILE SEMICONDUCTOR MEMORY DEVICE

(71) Applicant: KABUSHIKI KAISHA TOSHIBA, Tokyo (JP)

(72) Inventors: Natsuki SAKAGUCHI, Tokyo (JP); Hiroshi MAEJIMA, Tokyo (JP)

(73) Assignee: KABUSHIKI KAISHA TOSHIBA, Tokyo (JP)

(21) Appl. No.: 14/014,244

(22) Filed: Aug. 29, 2013

(30) Foreign Application Priority Data
Feb. 21, 2013 (JP) 2013-032270

(51) Int. Cl. G11C 16/26

(52) U.S. Cl. CPC G11C 16/26
USPC 365/185.21

(57) ABSTRACT

A nonvolatile semiconductor memory device includes a memory cell, a bit line electrically connected to the memory cell, a sense amplifier that includes a first transistor having a first end electrically connected to the bit line, a second transistor electrically connected between a second end of the first transistor and ground, a third transistor electrically connected between a second end of the first transistor and a source line, and a controller configured to control the first, second, and third transistors after performing a program operation. After the program operation, the first and second transistors are turned on and then while the first transistor remains turned on, the second transistor is turned off and the third transistor is turned on.

### CROSS-REFERENCE TO RELATED APPLICATION

This application is based upon and claims the benefit of priority from Japanese Patent Application No. 2013-032270, filed Feb. 21, 2013, the entire contents of which are incorporated herein by reference.

### FIELD

Embodiments described herein relate to a nonvolatile semiconductor memory device.

### BACKGROUND

A 3-dimensional memory known as BiCS (Bit Cost Scalable) which is layered in the vertical direction and is formed through batch processing has been proposed as a NAND-type flash memory.

### DESCRIPTION OF THE DRAWINGS

FIG. 1 is a timing chart illustrating various voltages during a write operation according to a comparison example.

FIG. 2 is a block diagram illustrating an example configuration of a nonvolatile semiconductor memory device according to a first embodiment.

FIG. 3 is a perspective view of the nonvolatile semiconductor memory device according to the first embodiment.

FIG. 4 is a block diagram of a memory cell array according to the first embodiment.

FIG. 5 is a circuit diagram of a block according to the first embodiment.

FIG. 6 is a perspective view of memory strings according to the first embodiment.

FIG. 7 is an enlarged cross-sectional view of the memory strings in FIG. 6.

FIG. 8 is a circuit diagram of the memory strings in FIG. 6.

FIG. 9 is a circuit diagram of a sense amplifier according to the first embodiment.

FIG. 10 is a cross-sectional view of the memory cell array according to the first embodiment that illustrates an example of a write operation.

FIG. 11 is a cross-sectional view of the memory cell array according to the first embodiment that illustrates an example of the write operation.

FIG. 12 is a timing chart illustrating various voltages during the write operation according to the first embodiment.

FIG. 13 is a circuit diagram of the sense amplifier which is connected to a bit line in the nonvolatile semiconductor memory device according to the first embodiment that illustrates an operation during an equalizing period of the write operation.

FIG. 14 is a timing chart illustrating various voltages during a write operation according to a first modification example.

FIG. 15 is a timing chart illustrating various voltages during a write operation according to a second embodiment.

FIG. 16 is a circuit diagram of a sense amplifier which is connected to a bit line in the nonvolatile semiconductor memory device according to the second embodiment that illustrates an operation during an equalizing period in a write operation.

FIG. 17 is a timing chart illustrating various voltages during a write operation according to a second modification example.

### DETAILED DESCRIPTION

Embodiments provide a volatile semiconductor memory device, which suppresses voltage from rising when a write operation is performed.

A nonvolatile semiconductor memory device according to one embodiment includes: a memory cell, a bit line electrically connected to the memory cell, a sense amplifier that includes a first transistor having a first end electrically connected to the bit line, a second transistor electrically connected between a second end of the first transistor and ground, a third transistor electrically connected between a second end of the first transistor and a source line, and a controller configured to control the first, second, and third transistors after performing a program operation. After the program operation, the first and second transistors are turned on and then while the first transistor remains turned on, the second transistor is turned off and the third transistor is turned on.

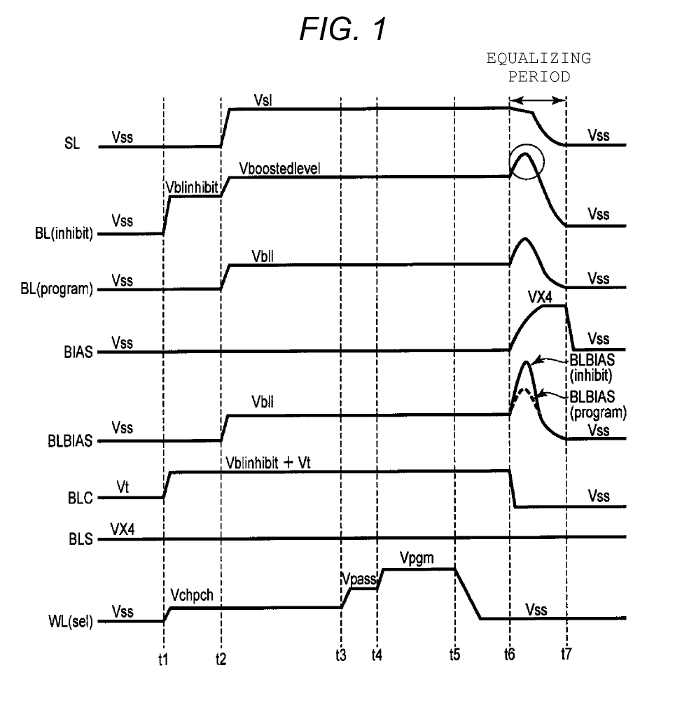

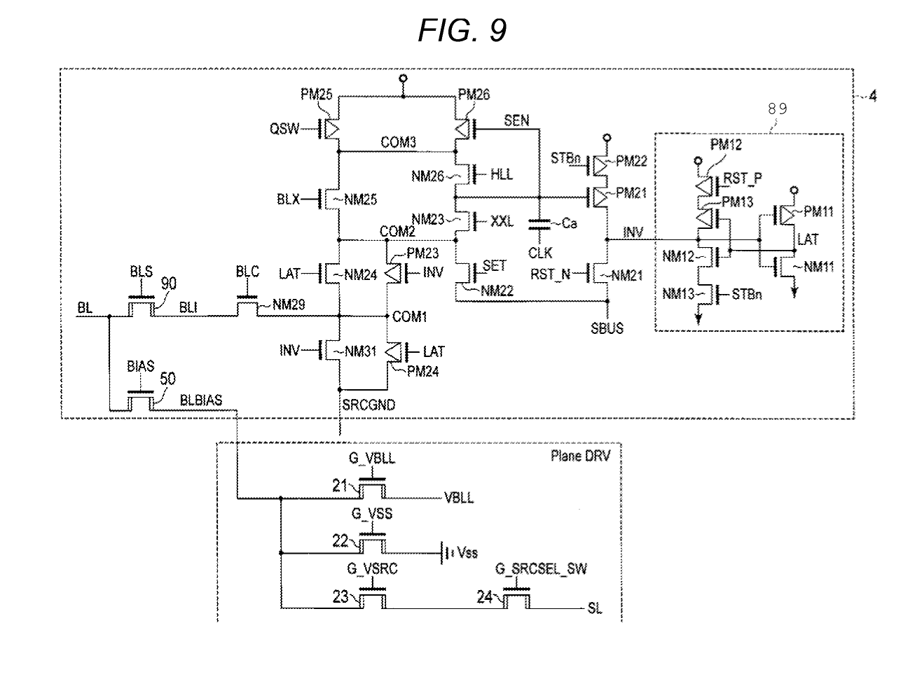

As shown in a comparison example in FIG. 1, in a BiCS, all the bit lines BL and all the source lines SL are equalized and the voltages thereof are decreased at the end (times t6 to t7) of a write (program) operation. At this time, an NMOS transistor NM29 and a transistor 50 in a sense amplifier 4 (see FIG. 9), which will be described later, are connected to each bit line BL. Further, when the NMOS transistor NM29 is turned off and the transistor 50 is turned on, the bit line BL and the source line SL are equalized through a node BLBIAS. More specifically, at time t6, Vss is applied to the gate of the NMOS transistor NM29 as a signal BLC, and a voltage VX4 is applied to the gate of the transistor 50 as a signal BIAS.

At time t6, a voltage Vsl of the source line SL is greater than a voltage Vbll of the write bit line BL (program) (Vsl>Vbll). Therefore, the voltage of the write bit line BL (program) rises from the voltage Vbll due to the equalization with the voltage Vsl of the source line SL. Meanwhile, at time t6, the voltage Vsl of the source line SL is less than a voltage Vboostedlevel of a write inhibition bit line BL (inhibit) (Vboostedlevel>Vsl). Therefore, the voltage of the write inhibition bit line BL (inhibit) drops from the voltage Vboostedlevel due to the equalization with the voltage Vsl of the source line SL.

However, it takes a little time to turn on the transistor 50, the bit line BL becomes a floating state temporarily. Therefore, immediately after time t6, the voltage of the write bit line BL (program) does not rise and the voltage of the write inhibition bit line BL (inhibit) does not drop as described above.

Therefore, as shown in FIG. 1, if the voltage of the write bit line BL (program) rises due to the equalization with the source line SL when the write inhibition bit line BL (inhibit) is in the floating state, the voltage of the write inhibition bit line BL (inhibit) rises due to the coupling with the write bit line BL (program). More specifically, the voltage of the write bit line BL (program) rises above the voltage Vbll and the voltage of the write inhibition bit line BL (inhibit) rises above the voltage Vboostedlevel.

Therefore, there is a case in which the voltage of the write inhibition bit line BL (inhibit) exceeds the pressure resistance limit of the NMOS transistor NM29, and, as a result, the NMOS transistor NM29 is destroyed.

Here, embodiments provide a nonvolatile semiconductor memory device which suppresses the voltage from rising excessively during the write operation.

Embodiments will be described in detail with reference to the accompanying drawings below. In the drawings, the same reference numerals are used to indicate the same sections and elements. In addition, redundant descriptions are made as necessary.

### First Embodiment

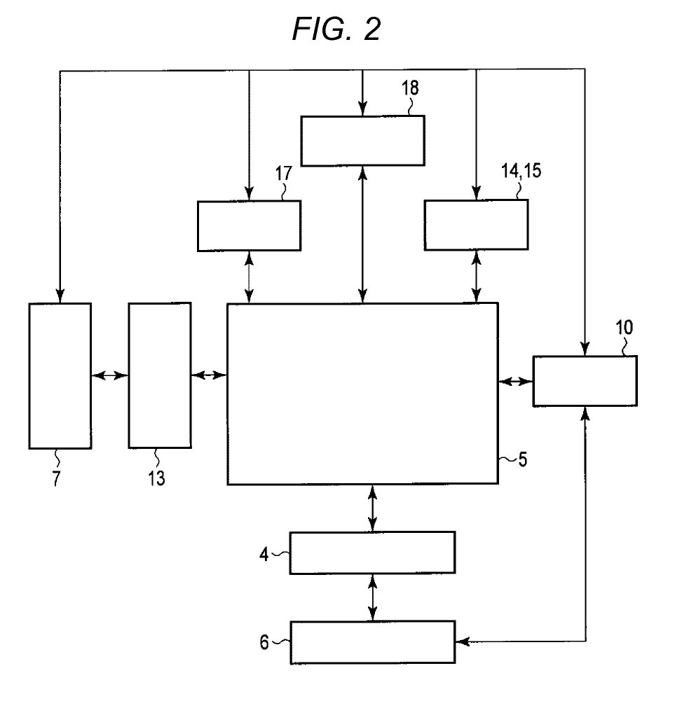

A nonvolatile semiconductor memory device according to a first embodiment will be described with reference to FIGS. 2 to 14. In the first embodiment, when the bit line BL (the write bit line BL (program) and the write inhibition bit line BL (inhibit)) are equalized with the source line SL through the node BLBIAS, the node BLBIAS is temporarily connected to a ground voltage (voltage Vss). Therefore, it is possible to suppress the voltage of the bit line BL from rising to exceed the pressure resistance limit of the NMOS transistor NM29. Hereinafter, the nonvolatile semiconductor memory device according to the first embodiment will be described in detail.

### Example of Whole Configuration

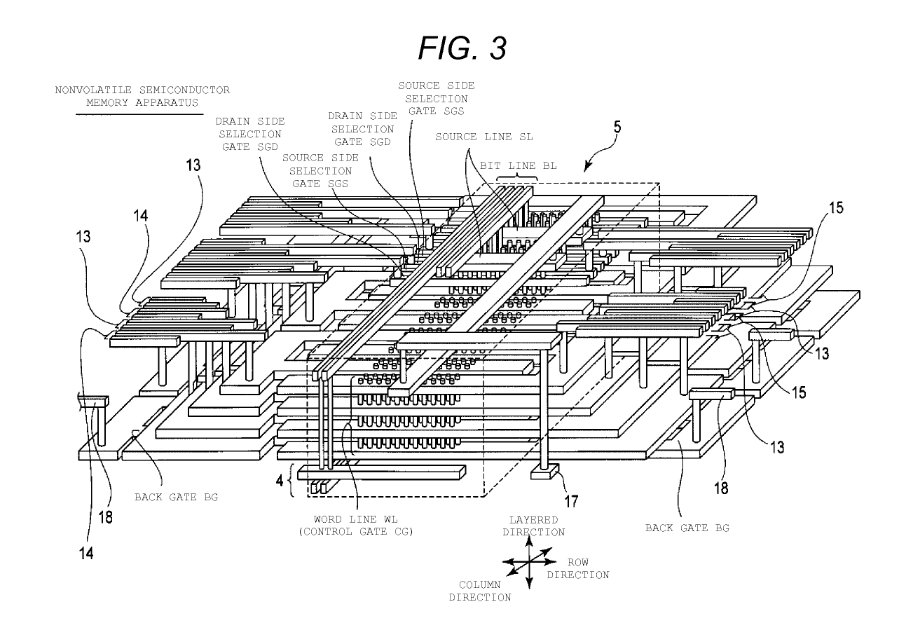

Hereinafter, an example of the whole configuration of the nonvolatile semiconductor memory device according to the first embodiment will be described with reference to FIGS. 2 and 3.

FIG. 2 is a block diagram illustrating an example of the whole configuration of the nonvolatile semiconductor memory device according to the first embodiment.

As shown in FIG. 2, the nonvolatile semiconductor memory device includes a control circuit 10, a sense amplifier 4, a memory cell array 5, a column decoder 6, a row decoder 7, a word line driving circuit 13, a selection gate line driving circuit (a source side selection gate line driving circuit 14 and a drain side selection gate line driving circuit 15), a source line driving circuit 17, and a back gate line driving circuit 18.

The memory cell array 5 includes a plurality of blocks BLK. Each of the plurality of blocks BLK includes a plurality of word lines WL and bit lines BL, and a plurality of memory strings (NAND strings) 40 which are arranged in a matrix configuration.

During a write operation, a read operation, and an erasing operation, the control circuit 10 generates and controls a voltage which is supplied to memory cells in the memory cell array 5, and controls the sense amplifier 4, the column decoder 6, the row decoder 7, the selection gate line driving circuit, the source line driving circuit 17, and the back gate line driving circuit 18 in response to a command from the outside.

The column decoder 6 selects a bit line BL under the control of the control circuit 10 during the write operation, the read operation, and the erasing operation.

The sense amplifier 4 is connected to the column decoder 6, and supplies a voltage to the bit line BL which is selected or not selected by the column decoder 6 during the write operation, the read operation, and the erasing operation. Meanwhile, the sense amplifier 4 may be integrally formed with the column decoder 6.

The row decoder 7 selects a word line WL under the control of the control circuit 10 during the write operation, the read operation, and the erasing operation.

The word line driving circuit 13 is connected to the row decoder 7, and supplies a voltage to the word line WL which is selected or not selected by the row decoder 7 during the write operation, the read operation, and the erasing operation. Meanwhile, the word line driving circuit 13 may be integrally formed with the row decoder 7.

The selection gate line driving circuit supplies a voltage to the selection gate SG under the control of the control circuit 10 during the write operation, the read operation, and the erasing operation.

The source line driving circuit 17 supplies a voltage to the source line SL under the control of the control circuit 10 during the write operation, the read operation, and the erasing operation.

The back gate line driving circuit 18 supplies a voltage to the back gate BG under the control of the control circuit 10 during the write operation, the read operation, and the erasing operation.

FIG. 3 is a perspective diagram illustrating an example of the whole configuration of the nonvolatile semiconductor memory device according to the first embodiment.

As shown in FIG. 3, in the memory cell array 5, a plurality of word lines WL (control gates CG), a plurality of bit lines BL, a plurality of source lines SL, a plurality of back gates BG, a plurality of source side selection gates SGS, and a plurality of drain side selection gates SGD are provided.

In the memory cell array 5, memory cell transistors MTr, which store data, are disposed at the respective cross sections of the plurality of layered word lines WL and U-shaped semiconductor pillars SP which will be described later.

The ends of the plurality of layered word lines WL are formed in a stepwise shape in the row direction, and contacts are connected to the upper surfaces of the respective steps. The respective contacts have upper portions which are connected to wirings. In addition, in the column direction, even numbered control gates CG are connected to each other at one end in the row direction, and odd numbered control gates CG are connected to each other at the other end in the row direction. Meanwhile, although FIG. 3 shows the example in which the word lines WL are layered in 4 layers, the invention is not limited thereto.

In addition, the contacts are respectively connected to the upper surfaces of the ends of the source lines SL, the back gates BG, the source side selection gates SGS, and the drain side selection gates SGD in the row direction, and the wirings are connected to the upper sections.

The word line driving circuit 13 is connected to the word lines WL through the wirings and the contacts which are formed on the upper sections.

The source side selection gate line driving circuit 14 is connected to the source side selection gates SGS through the wirings and the contacts which are formed on the upper sections.

The drain side selection gate line driving circuit 15 is connected to the drain side selection gates SGD through the wirings and the contacts which are formed on the upper sections.

The back gate driving circuit 18 is connected to the back gates BG through the wirings and the contacts which are formed on the upper sections.

The source line driving circuit 17 is connected to the source lines SL through the wirings and the contacts which are formed on the upper sections. There is provided a plurality of source line driving circuits 17. The respective source line driving circuits 17 are commonly connected to a predetermined number of source lines SL, and are independently controlled by the control circuit 10.

The sense amplifier 4 is connected through contacts which are connected to the lower surfaces of the ends of the bit lines BL in the column direction.

In addition, in FIG. 3, although all the wirings which are connected to the various driving circuits are formed in the same-level wiring layer, the invention is not limited thereto. The wirings may be formed in different-level wiring layers. In addition, although the number of various driving circuits is determined based on the number of respective gates, a single driving circuit may be connected to a single gate or a single driving circuit may be connected to a predetermined number of gates.

### Example of Configuration of Memory Cell Array

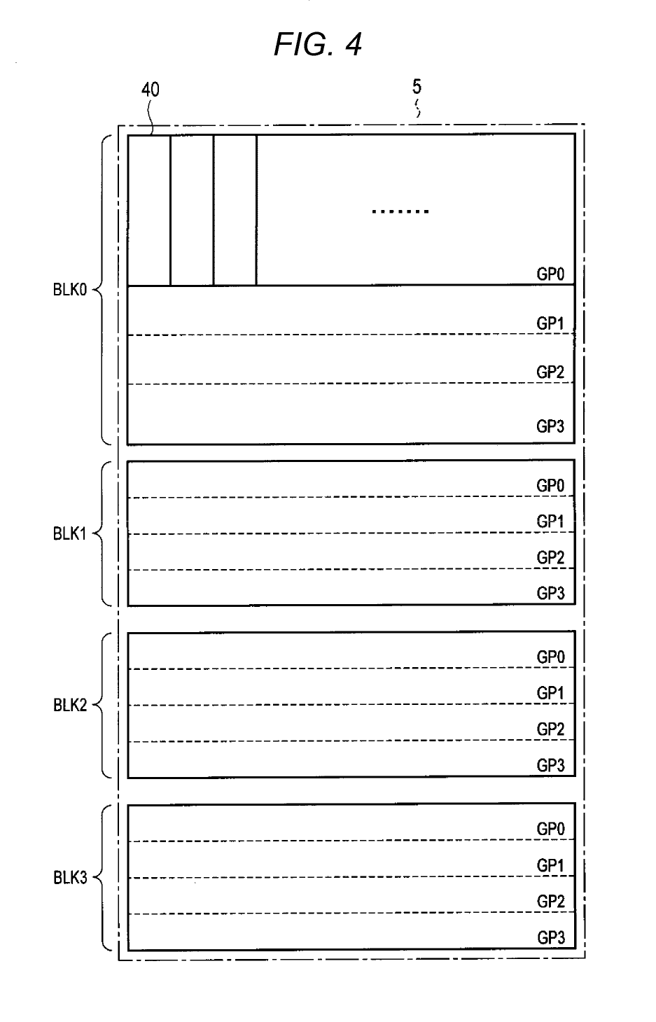

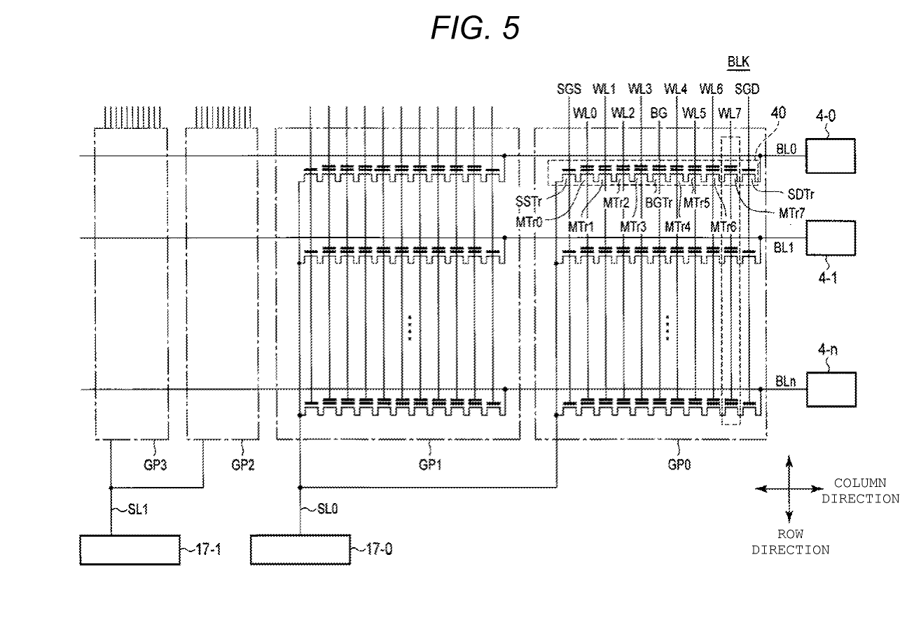

Hereinafter, an example of the configuration of the memory cell array 5 according to the first embodiment will be described with reference to FIGS. 4 and 5.

FIG. 4 is a block diagram illustrating the memory cell array 5 according to the first embodiment.

As shown in FIG. 4, the memory cell array 5 includes a plurality of blocks (here, blocks BLK0 to BLK3). Each block BLK includes a plurality of memory groups (here, memory groups GP0 to GP3). Each memory group GP includes a plurality of memory strings 40. The erasing operation is performed for each block BLK in the memory cell array 5. In the description below, when it is not necessary to refer to a particular block or a particular memory group, blocks BLK0 to BLK3 are referred to as the block BLK and the memory groups GP0 to GP3 are referred to as the memory group GP.

FIG. 5 is a circuit diagram illustrating the block BLK according to the embodiment.

As shown in FIG. 5, the block BLK includes, for example, four memory groups GP0 to GP3 which are disposed in the column direction. In addition, each memory group GP includes n (n is a natural number) memory strings 40 which are disposed in the row direction.

Each of the memory strings 40 includes, for example, eight memory cell transistors MTr0 to MTr7, a source side selection transistor SSTr, a drain side selection transistor SDTr, and a back gate transistor BGTr. The memory cell transistors MTr0 to MTr7, the source side selection transistor SSTr, the drain side selection transistor SDTr, and the back gate transistor BGTr have current paths connected in series. One end of the source side selection transistor SSTr is connected to one end of the current path (here, one end of the memory cell transistor MTr0), and one end of the drain side selection transistor SDTr is provided on the other end of the current path (here, one end of the memory cell transistor MTr7). In addition, the back gate transistor BGTr is provided between the memory cell transistor MTr3 and the memory cell transistor MTr4.

Meanwhile, the number of memory cell transistors MTr is not limited to eight. The number of memory cell transistors may be 16, 32, 64, 128, or the like, and the number is not limited. In addition, FIG. 5 illustrates that the current paths of the memory strings 40 are parallel in the column direction. In the first embodiment, the current paths of the memory strings 40 are parallel in the layered direction as will be described later.

The gates of the source side selection transistors SSTr in the same memory group GP are commonly connected to the source side selection gate SGS and the gates of the drain side selection transistors SDTr in the same memory group GP are commonly connected to the drain side selection gate SGD. In addition, the control gates of the memory cell transistors MTr0 to MTr7 in the same block BLK are commonly connected to the word lines WL0 to WL7 and the control gates of the back gate transistors BT are commonly connected to the back gate BG.

That is, the word lines WL0 to WL7 and the back gate BG are commonly connected between the plurality of memory groups GP0 to GP3 in the same block BLK. In contrast, the source side selection gate SGS and the drain side selection gate SGD are independent for the respective memory groups GP0 to GP3, even within the same block BLK.

In the memory strings 40 which are arranged in the matrix configuration in the memory cell array 5, the other ends of the current paths of the drain side selection transistors SDTr of the memory strings 40 which are disposed in the column direction are commonly connected to one of the bit lines BL (BL0 to BLn, n is a natural number). That is, the bit lines BL commonly connect the memory strings 40 between the plurality of blocks BLK. The respective bit lines BL0 to BLn are connected to the sense amplifiers 4-0 to 4-n on the outside of the memory cell array 5. Therefore, the voltage levels of the bit lines BL0 to BLn are independently controlled.

The other ends of the current paths of the source side selection transistors SSTr in the memory group GP are commonly connected to the source line SL. In the block BLK, a plurality of source lines SL (here, source lines SL0 and SL1) are disposed. The source line SL0 is commonly connected to the other ends of the current paths of the source side selection transistors SSTr in the memory groups GP0 and GP1, and the source line SL1 is commonly connected to the other ends of the current paths of the source side selection transistors SSTr in the memory groups GP2 and GP3. That is, the source line SL commonly connects the memory strings 40 between two adjacent memory groups GP. The source lines SL0 and SL1 are respectively connected to the source line driving circuits 17-0 and 17-1 on the outside of the memory cell array. Therefore, the voltage levels of the source lines SL0 and SL1 are independently controlled.

Meanwhile, the number of source lines SL is not limited thereto and is determined depending on the number of the memory groups GP in the block BLK.

As described above, the data of the memory cell transistors MTr in the same block BLK are collectively erased. In contrast, the reading and writing of data are collectively performed on a plurality of memory cell transistors MTr which are commonly connected to a word line WL, which may be in any memory group GP of any block BLK. The unit of read and write operations is called a “page”.

### Example of Configuration of Memory Strings

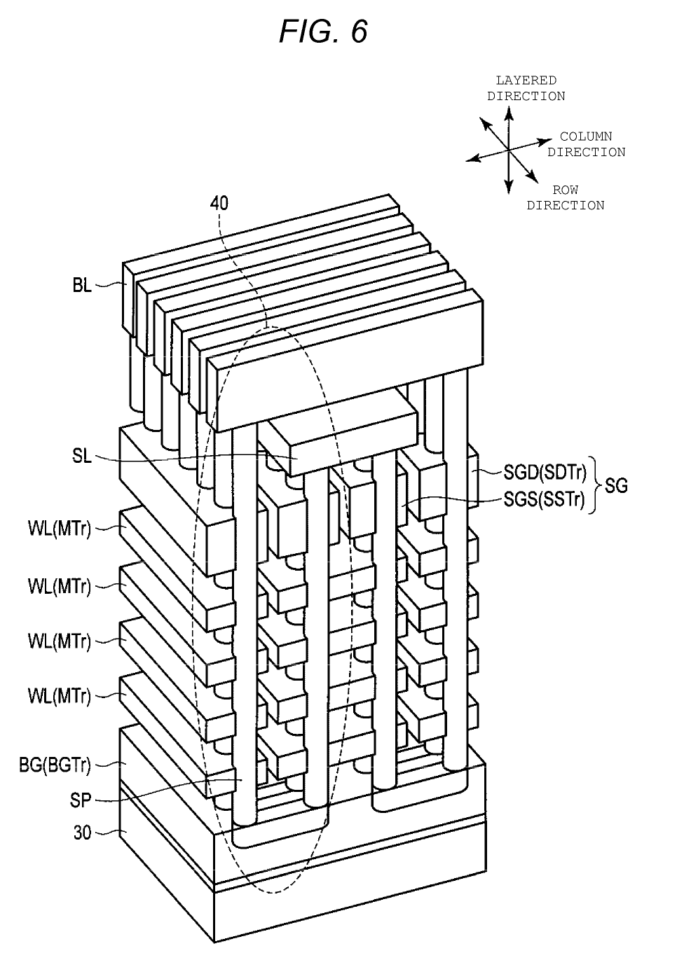

Hereinafter, an example of the configuration of a memory string 40 according to the first embodiment will be described with reference to FIGS. 6 to 8.

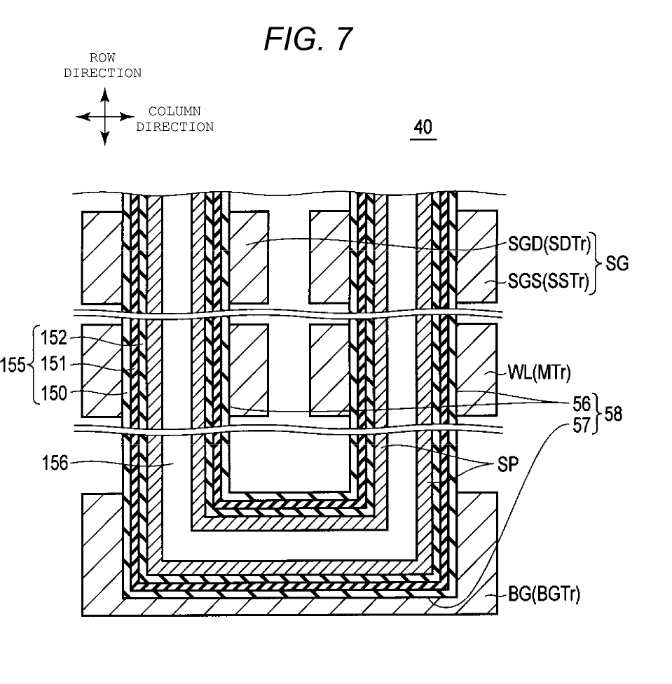

FIG. 6 is a perspective diagram illustrating the memory string 40 according to the first embodiment. FIG. 7 is a cross-sectional view enlarging the memory string 40 in FIG. 6.

As shown in FIGS. 6 and 7, in the memory cell array 5, the memory string 40 is formed on the upper side of a semiconductor substrate 30, and includes a back gate BG, a plurality of word lines WL, a selection gate SG, a U-shaped semiconductor pillar SP, and a memory layer 155.

The back gate BG is formed on the semiconductor substrate 30 with an insulating layer, which is not shown in the drawing, interposed therebetween. The back gate BG is formed to be broadened in a plane shape. The back gate BG is configured by a conductive layer formed of, for example, polysilicon (poly-Si) or the like into which impurities (for example, phosphorus) are introduced.

The plurality of word lines WL are formed on the back gate BG with interelectrode insulating layers, which are not shown in the drawing, interposed therebetween. In other words, the plurality of interelectrode insulating layers and the plurality of word lines WL are alternately layered on the back gate BG. The word lines WL are configured by conductive layers formed of, for example, poly-Si, metal, or the like into which impurities (for example, boron) are introduced.

The selection gate SG is formed on a word line WL on the uppermost layer with an insulating layer, which is not shown in the drawing, interposed therebetween. Similar to the word line WL, the selection gate SG is configured by a conductive layer formed of, for example, poly-Si, metal, or the like into which impurities are introduced.

The source line SL is formed on the upper side of the selection gate SG with an insulating layer, which is not shown in the drawing, interposed therebetween, and the bit line BL is formed on the further upper side with an insulating layer, which is not shown in the drawing, interposed therebetween.

A memory hole 58 is provided in the selection gate SG, the word lines WL, the back gate BG, and the interelectrode insulating layer. The memory hole 58 includes a pair of through holes 56 which are disposed in the column direction, and a connection hole 57 which connects the lower ends of the pair of through holes 56. The through holes 56 are formed to expand in the layered direction in the selection gate SG, the word lines WL, and the interelectrode insulating layer. The connection hole 57 is formed to expand in the column direction in the back gate BG.

In addition, a slit which is not shown in the drawing and which expands in the row direction and the layered direction is provided between the pair of through holes 56 in the word lines WL and the interelectrode insulating layer. Therefore, the word lines WL and the interelectrode insulating layer are divided along the row direction. Further, in the selection gate SG, an opening section which expands in the row direction and the layered direction and which is not shown in the drawing is provided in the upper section of the silt such that the silt is open. Therefore, the selection gate SG is divided along the row direction, one of the selection gates obtained through the division becomes a drain side selection gate SGD and the other selection gate becomes a source side selection gate SGS. For example, an insulating material is buried in the slit and the opening section.

The memory layer 155 is formed on the inner surface of the memory hole 58. That is, the memory layer 155 is formed on the selection gate SG, the word lines WL, the back gate BG, and the interelectrode insulating layer in the memory hole 58. The memory layer 155 includes a block insulating layer 150, a charge storage layer 151, and a tunnel insulating layer 152 which are sequentially formed from the inner surface of the memory hole 58.

The U-shaped semiconductor pillar SP is formed on the memory layer 155 in the memory hole 58. That is, the U-shaped semiconductor pillar SP includes a pair of pillar sections which are formed on the memory layer 155 in the pair of through holes 56, and a connection section which is formed on the memory layer 155 in the connection hole 57. The U-shaped semiconductor pillar SP is configured by a conductive layer formed of poly-Si, amorphous silicon (a-Si), or the like which includes impurities (for example, phosphorus), and functions as a channel.

A core layer 156 is formed on the U-shaped semiconductor pillar SP in the memory hole 58. The core layer 156 is configured by an insulating layer formed of, for example, oxide silicon (for example, SiO₂), and thus the inside of the memory hole 58 is buried. Meanwhile, the core layer 156 may be hollow, and the inside of the memory hole 58 may not be buried.

In addition, although not shown in the drawing, a section which comes into contact with the insulating material (the slit and the opening section) of the selection gate SG and the word line WL may be formed of silicide.

Various transistors are configured with the U-shaped semiconductor pillar SP, the memory layer 155 formed in the vicinity of the U-shaped semiconductor pillar SP, and the various gates. Further, the U-shaped semiconductor pillar SP is used as a channel, and the memory string 40 is configured along the U-shaped semiconductor pillar SP.

More specifically, a memory cell transistor MTr is configured with the word lines WL, the U-shaped semiconductor pillar SP, and the memory layer 155 which is formed therebetween. In addition, the selection transistor (the drain side selection transistor SDTr and the source side selection transistor SSTr) is configured with the selection gate SG (the drain side selection gate SGD and the source side selection gate SGS), the U-shaped semiconductor pillar SP, and the memory layer 155 which is formed therebetween.

In addition, the back gate transistor BGTr is configured with the back gate BG, the U-shaped semiconductor pillar SP, and the memory layer 155 which is formed therebetween. A voltage is applied to the back gate BG such that the back gate transistor BGTr is usually turned on.

Meanwhile, it should be understood that the memory layer 155 does not store data and simply functions as a gate insulating film in the selection transistor and the back gate transistor BGTr.

A group of the plurality of memory strings 40 which are disposed along the row direction in FIG. 6 corresponds to the memory group GP described in FIG. 5.

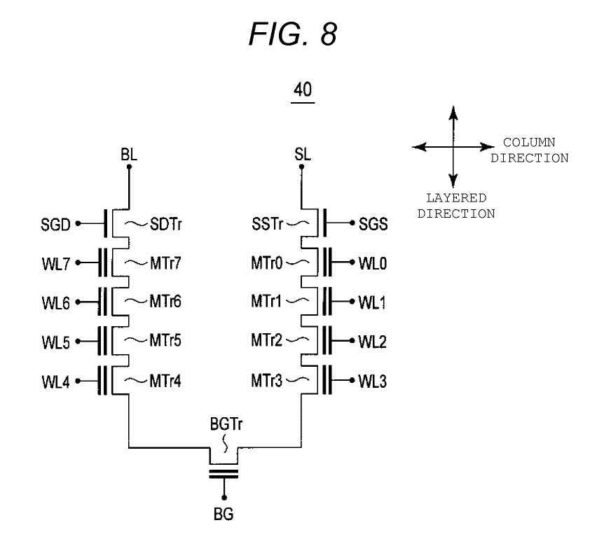

FIG. 8 is a circuit diagram illustrating the memory string 40 in FIG. 6.

As shown in FIG. 8, the memory string 40 includes a source side selection transistor SSTr, a drain side selection transistor SDTr, memory cell transistors MTr0 to MTr7, and a back gate transistor BGTr.

As described above, the memory cell transistors MTr0 to MTr7 have current paths which are connected in series between the source side selection transistor SSTr and the drain side selection transistor SDTr. The back gate transistor BGTr has the current paths which are connected in series between the memory cell transistors MTr3 and MTr4.

More specifically, the current paths of the memory cell transistors MTr0 to MTr3 and the current paths of the memory cell transistors MTr4 to MTr7 are connected in series in the layered direction, respectively. Further, since the back gate transistor BGTr is disposed between the memory cell transistors MTr3 and MTr4 on the lower side in the layered direction, the current paths are connected in series. That is, along the U-shaped semiconductor pillar shown in FIG. 6, the current paths of the source side selection transistor SSTr, the drain side selection transistor SDTr, the memory cell transistors MTr0 to MTr7, and the back gate transistor BGTr are connected in series as the memory string 40. When the write operation and the read operation are performed on data, the back gate transistor BGTr is usually in an On state.

In addition, the control gates of the memory cell transistors MTr0 to MTr7 are connected to the word lines WL0 to WL7 and the control gate of the back gate transistor BGTr is connected to the back gate BG. In addition, the gate of the source side selection transistor SSTr is connected to the source side selection gate SGS, and the gate of the drain side selection transistor SDTr is connected to the drain side selection gate SGD.

### Example Configuration of Sense Amplifier

Hereinafter, an example configuration of the sense amplifier 4 according to the first embodiment will be described with reference to FIG. 9.

FIG. 9 is a circuit diagram illustrating the sense amplifier 4 according to the first embodiment. In the example, the sense amplifier 4 can apply any of voltages Vss, Vbll, Vbl, and Vblinhibit to a corresponding bit line BL when a write operation is performed. Meanwhile, the respective voltages Vss, Vbll, Vbl, and Vblinhibit have the relationship of Vss<Vbll<Vbl<Vblinhibit.

Here, the sense amplifier 4 represents any one of the sense amplifiers 4-0 to 4-n shown in FIG. 5. In addition, all the sense amplifiers 4-0 to 4-n have the same configuration.

As shown in FIG. 9, the sense amplifier 4 includes an inner latch circuit 89 which stores write data or read data.

The inner latch circuit 89 includes p-channel MOS transistors (hereinafter, called PMOS transistors) PM11, PM12, and PM13, and n-channel MOS transistors (hereinafter, called NMOS transistors) NM11, NM12, and NM13.

One end of the current path of the PMOS transistor PM11 is connected to the power-supply voltage of the sense amplifier 4, and the other end is connected to one end of the current path of the NMOS transistor NM11. The other end of the current path of the NMOS transistor NM11 is connected to a ground voltage (voltage Vss). One end of the current path of the PMOS transistor PM12 is connected to the power-supply voltage, and the other end is connected to one end of the current path of the PMOS transistor PM13. The other end of the current path of the PMOS transistor PM13 is connected to one end of the current path of the NMOS transistor NM12. The other end of the current path of the NMOS transistor NM12 is connected to one end of the current path of the NMOS transistor NM13. The other end of the current path of the NMOS transistor NM13 is connected to the ground voltage.

The respective gates of the PMOS transistor PM11 and the NMOS transistor NM11 are commonly connected to the connection point between the other end of the current path of the PMOS transistor PM13 and the one end of the current path of the NMOS transistor NM12, and a signal INV is applied to the respective gates. The respective gates of the PMOS transistor PM13 and NMOS transistor NM12 are commonly connected to the connection point between the other end of the current path of the PMOS transistor PM11 and the one end of the current path of the NMOS transistor NM11, and a signal LAT which has a phase reversed to that of the signal INV is applied to the respective gates. A signal RST_P is applied to the gate of the PMOS transistor PM12 and a signal STBn is applied to the gate of the NMOS transistor NM13.

In addition, the respective gates of the PMOS transistor PM11 and the NMOS transistor NM11 are commonly connected to a connection point between one end of the current path of the PMOS transistor PM21 and one end of the current path of the NMOS transistor NM21.

The other end of the current path of the PMOS transistor PM21 is connected to the power-supply voltage of the sense amplifier 4 through a PMOS transistor PM22. The other end of the current path of an NMOS transistor NM21 is connected to one end of the current path of an NMOS transistor (SET transistor) NM22 and is connected to a data bus (SBUS line). Therefore, a signal BUS is applied to the other end of the current path of the NMOS transistor NM21 and the one end of the current path of the NMOS transistor NM22.

A signal RST_N is applied to the gate of the NMOS transistor NM21, and the signal STBn is applied to the gate of the PMOS transistor PM22. An electrode on one side of a capacitor Ca is connected to a node SEN and the potential of the node SEN (signal SEN) is applied to the gate of the PMOS transistor PM21. A signal CLK, which is a clock, is applied to an electrode on the other side of the capacitor Ca. In addition, a signal SET is applied to the gate of the NMOS transistor NM22.

The other end of the current path of the NMOS transistor NM22 is connected to a node COM2. That is, the other end of the current path of the NMOS transistor NM22 is connected to a connection point between one end of the current path of an NMOS transistor NM23 and one end of the current path of a PMOS transistor PM23 and a connection point between one end of the current path of an NMOS transistor NM24 and one end of the current path of an NMOS transistor NM25, respectively.

The other end of the current path of the NMOS transistor NM23 is connected to the gate of the PMOS transistor PM21 and one end of the current path of an NMOS transistor NM26, respectively. The other end of the current path of the NMOS transistor NM26 is connected to a node COM3. That is, the other end of the current path of the NMOS transistor NM26 is connected to a connection point between the other end of the current path of the NMOS transistor NM25 and one end of the current path of a PMOS transistor PM25 and one end of the current path of a PMOS transistor PM26, respectively. The power-supply voltage is commonly connected to the other end of the current path of the PMOS transistor PM25 and the other end of the current path of the PMOS transistor PM26.

A signal XXL is applied to the gate of the NMOS transistor NM23, the signal INV is applied to the gate of the PMOS transistor PM23, the signal LAT is applied to the gate of the NMOS transistor NM24, a signal BLX is applied to the gate of the NMOS transistor NM25, a signal HLL is applied to the gate of the NMOS transistor NM26, a signal QSW is applied to the gate of the PMOS transistor PM25, and the signal SEN is applied to the gate of the PMOS transistor PM26, respectively.

The common connection point between the other end of the current path of the PMOS transistor PM23 and the other end of the current path of the NMOS transistor NM24 is connected to one end of the current path of an NMOS transistor (clamp transistor) NM29, one end of the current path of an NMOS transistor NM31, and one end of the PMOS transistor PM24, respectively. The other end of the current path of the NMOS transistor NM29 is connected to one end of the current path of a transistor 90, and a signal BLC is applied to the gate of the NMOS transistor NM29. The other end of the current path of the NMOS transistor NM31 is connected to the other end of the PMOS transistor PM24 and a common source line (node SRCGND), and the signal INV is applied to the gate of the NMOS transistor NM31. The signal LAT is applied to the gate of the PMOS transistor PM24. The other end of the current path of the transistor 90 is connected to the bit line BL, and a signal BLS is applied to the gate of the transistor 90. In addition, the transistor 90 is high pressure-resistant.

In the first embodiment, the sense amplifier 4 (sense amplifiers 4-0 to 4-n) includes a high pressure resistant transistor 50 which is disposed between the bit line BL and the source line SL.

One end of the current path of the transistor 50 is connected to the other end of the transistor 90 and the bit line BL, and a signal BIAS is applied to the gate of the transistor 50. The other end of the current path of the transistor 50 is connected to a node BLBIAS. The node BLBIAS is commonly connected to one ends of high pressure-resistant transistors 21, 22, and 23 which are provided in a peripheral circuit (Plane DRV). In other words, the current paths of the transistors 21, 22, and 23 are connected to each other in parallel.

The other end of the transistor 21 is connected to a node VBLL, and a signal G_VBLL is applied to the gate of the transistor 21. Therefore, it is possible to supply the voltage Vbll to the node BLBIAS through the transistor 21.

The other end of the transistor 22 is connected to the ground voltage, and a signal G_VSS is applied to the gate of the transistor 22. Therefore, it is possible to supply the voltage Vss to the node BLBIAS through the transistor 22.

The other end of the transistor 23 is connected to one end of a high pressure-resistant transistor 24, and a signal G_VSRC is applied to the gate of the transistor 23. In addition, the other end of the transistor 24 is connected to the source line SL, and a signal G_SRCSEL_SW is applied to the gate of the high pressure-resistant transistor 24. Therefore, it is possible to electrically connect the source line SL to the node BLBIAS through the transistors 23 and 24. Further, it is possible to electrically connect (equalize) the bit line BL to the source line SL through the transistor 50.

During the write operation, the equalization of the potentials of the bit line BL and the source line SL through the node BLBIAS is controlled by turning on the transistors 23 and 24 and controlling an on/off timing of the transistor 50 of the sense amplifier 4. That is, the transistor 50 functions as an equalizer switch.

Meanwhile, the respective signals are supplied by the corresponding column decoder 6 or the control circuit 10.

Hereinafter, the write operation performed by the sense amplifier 4 will be described in brief. Here, the supply of the voltages (voltages Vbll and Vblinhibit, Vbll<Vblinhibit<Vddsa) to the bit line BL (the write bit line BL (program) and the write inhibition bit line BL (inhibit)) from the sense amplifier 4 during the write operation will be described.

When the voltage Vblinhibit is supplied to the write inhibition bit line BL (inhibit), the voltage is supplied from the power-supply voltage (voltage Vddsa).

More specifically, ‘H (for example, VTH)’ is applied as the signal BLX. The voltage VTH has a sufficient size to transmit the voltage Vddsa. In addition, ‘H (for example, Vddsa)’ is applied as the signal LAT. In addition, an ‘L (Vss)’ level is applied as the signals QSW and INV. Therefore, the PMOS transistors PM25 and PM23 and the NMOS transistors NM24 and NM25 are turned on. On the other hand, the NMOS transistor NM31 and the PMOS transistor PM24 are turned off. Therefore, the voltage Vddsa is transmitted from the power-supply voltage to the node COM1. Further, as will be described later, a voltage [Vblinhibit+Vt (which is the threshold voltage of the NMOS transistor NM29 and which is used in the same manner below)] is applied as the signal BLC, and a voltage VX4 is applied as the signal BLS. The voltage VX4 is used to turn on the transistor 90 and has a sufficient size to transmit the voltage Vblinhibit. Therefore, the voltage Vblinhibit is transmitted from the node COM1 to the write inhibition bit line BL (inhibit).

On the other hand, when the voltage Vbll is supplied to the write bit line BL (program), the voltage Vbll is supplied through the node SRCGND.

More specifically, an ‘L (Vss)’ level is applied as the signal LAT. In addition, an ‘H (for example, Vddsa)’ level is applied as the signal INV. Therefore, the NMOS transistor NM31 and the PMOS transistor PM24 are turned on. On the other hand, the PMOS transistor PM23 and the NMOS transistor NM24 are turned off. Therefore, the voltage Vbll is transmitted to node COM1 through the node SRCGND. Further, similar to the sense amplifier 4 which is connected to the write inhibition bit line BL (inhibit), the voltage [Vblinhibit+Vt] is applied as the signal BLC and the voltage VX4 is applied as the signal BLS. Therefore, the voltage Vbll is transmitted from the node COM1 to the write bit line BL (program).

### Example of Write Operation

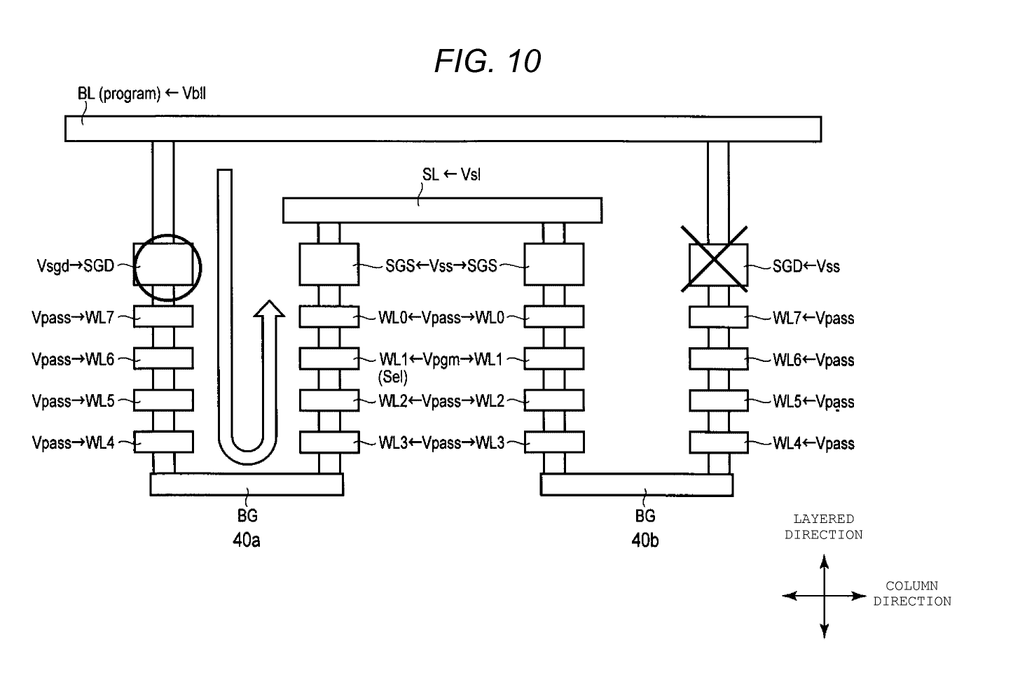

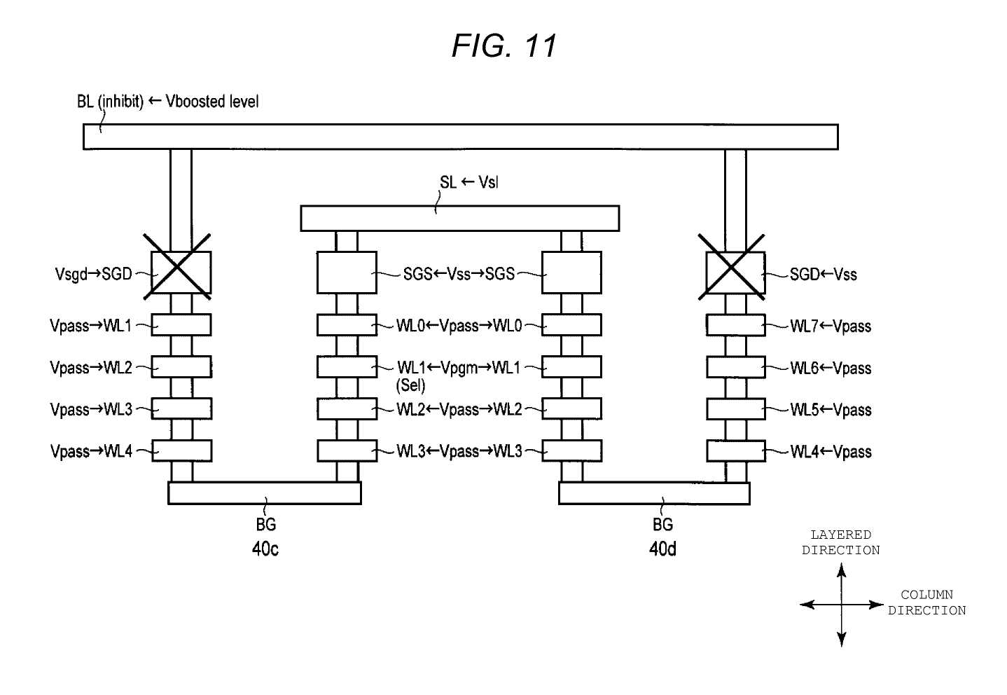

Hereinafter, an example of the write operation according to the first embodiment will be described with reference to FIGS. 10 and 11.

FIG. 10 is a cross-sectional view of the memory cell array according to the first embodiment that illustrates an example of the write operation. FIG. 11 is a cross-sectional view of the memory cell array according to the first embodiment that illustrates an example of the write operation.

Here, an example, in which memory strings 40a and 40c are selected (written) memory strings and memory strings 40b and 40d are non-selected (non-written) memory strings, is shown. In addition, an example, in which data “0 (high threshold)” is written in a memory cell which is connected to the word line WL1 of the memory string 40a and data “1 (low threshold)” is written in a memory cell which is connected to the word line WL1 of the memory string 40c, is shown. Meanwhile, although an example, in which the word lines WL0 to WL3 and the source side selection gate SGS of each of the selected memory string and the non-selected memory string which are adjacent in the column direction are separated from each other, is shown in FIGS. 10 and 11, the word lines WL0 to WL3 and the source side selection gates SGS may be integrally formed.

First, the write operation performed in the memory strings 40a and 40b which are commonly connected to the write bit line BL (program) and which are adjacent to each other in the column direction will be described.

As shown in FIG. 10, in the memory string 40a which is the selected memory string, the voltage Vbll is applied to the write bit line BL (program), and the voltage Vsl is applied to the source line SL. In addition, the voltage Vss (for example, 0 V) is applied to the source side selection gate SGS, and a voltage Vsgd is applied to the drain side selection gate SGD. Therefore, the drain side selection gate SGD is turned on and channel current flows. Further, a voltage Vpass is applied to the word lines WL0 and WL2 to WL7 which are connected to the non-selected memory cell, and a voltage Vpgm is applied to the word line WL1 which is connected to the selected memory cell (Vpass<Vpgm). Therefore, a high electrical field is applied to only the selected memory cell and data “0” is written.

On the other hand, since the memory string 40b which is the non-selected memory string is commonly connected to the memory string 40a, the voltage Vbll is applied to the write bit line BL (program), and the voltage Vsl is applied to the source line SL. In addition, the voltage Vss is applied to the source side selection gate SGS, and the voltage Vss is applied to the drain side selection gate SGD. Therefore, it is possible to turn off the drain side selection gate SGD. Since the memory string 40b is commonly connected to the memory string 40a, the voltage Vpgm is applied to the word line WL1. However, when the drain side selection gate SGD is turned off, memory cells which are connected to the word line WL1 are not written.

Meanwhile, in the BiCS, the threshold voltage of the drain side selection transistor SGD is negative. Therefore, when Vss is simply applied to the drain side selection gate SGD and a comparatively low voltage (for example, the voltage Vss) is applied to the bit line BL, the drain side selection transistor SDTr is turned on. In contrast, as shown in FIG. 11, when a comparatively high voltage (for example, the voltage Vbll) is applied to the bit line BL, it is possible to make the threshold of the drain side selection transistor SDTr be positive in a pseudo manner. Therefore, as described above, even when the voltage Vss is applied to the source side selection gate SGS in the memory string 40b, it is possible to turn off the drain side selection transistor SDTr.

Subsequently, a write operation performed in the memory strings 40c and 40d, which are commonly connected to the write inhibition bit line BL (inhibit) and which are adjacent to each other in the column direction, will be described.

As shown in FIG. 11, in the memory string 40c which is a selected memory string, a voltage Vboostedlevel is applied to the write inhibition bit line BL (inhibit). In addition, since the memory string 40c is commonly connected to the memory string 40a, the voltage Vsl is applied to the source line SL, the voltage Vss is applied to the source side selection gate SGS, and the voltage Vsgd is applied to the drain side selection gate SGD. At this time, the voltage Vsgd is applied to the drain side selection gate SGD. However, the voltage Vboostedlevel which is greater than the voltage Vbll is applied to the write inhibition bit line BL (inhibit), and it is possible to turn off the drain side selection gate SGD. In addition, since the memory string 40c is commonly connected to the memory string 40a, the voltage Vpgm is applied to the word line WL1. However, when the drain side selection gate SGD is turned off, data “0” write is not performed on the memory cell which is connected to the word line WL1. In other words, data “1” is written in the selected memory cell of the memory string 40c.

On the other hand, since the memory string 40d which is the non-selected memory string is commonly connected to the memory string 40c, the voltage Vboostedlevel is applied to the write inhibition bit line BL (inhibit) and the voltage Vsl is applied to the source line SL. In addition, the voltage Vss is applied to the source side selection gate SGS and the voltage Vss is applied to the drain side selection gate SGD. Therefore, it is possible to turn off the drain side selection gate SGD. Since the memory string 40d is commonly connected to the memory string 40c, the voltage Vpgm is applied to the word line WL1. However, when the drain side selection gate SGD is turned off, write is not performed on the memory cell which is connected to the word line WL1.

### Timing Chart of Voltage of Bit Line Bl in Write Operation

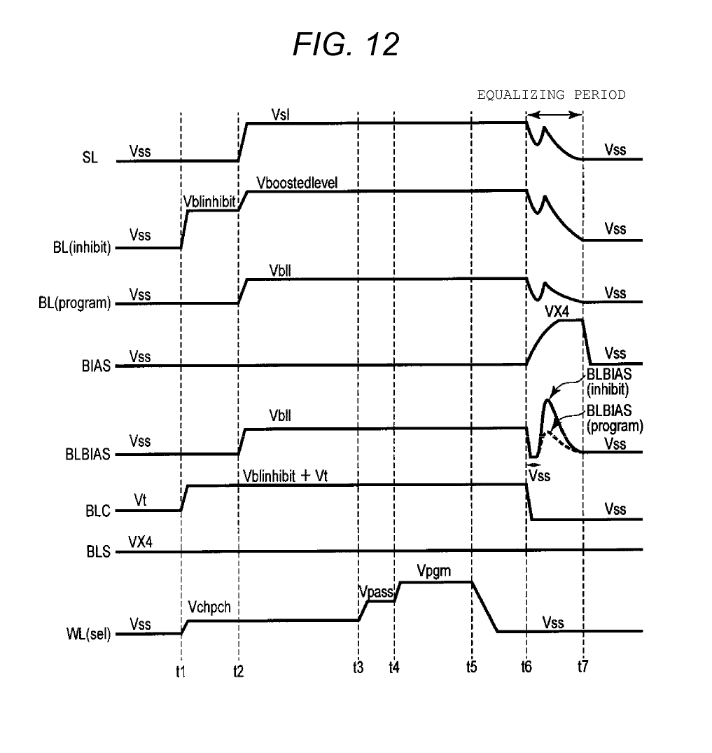

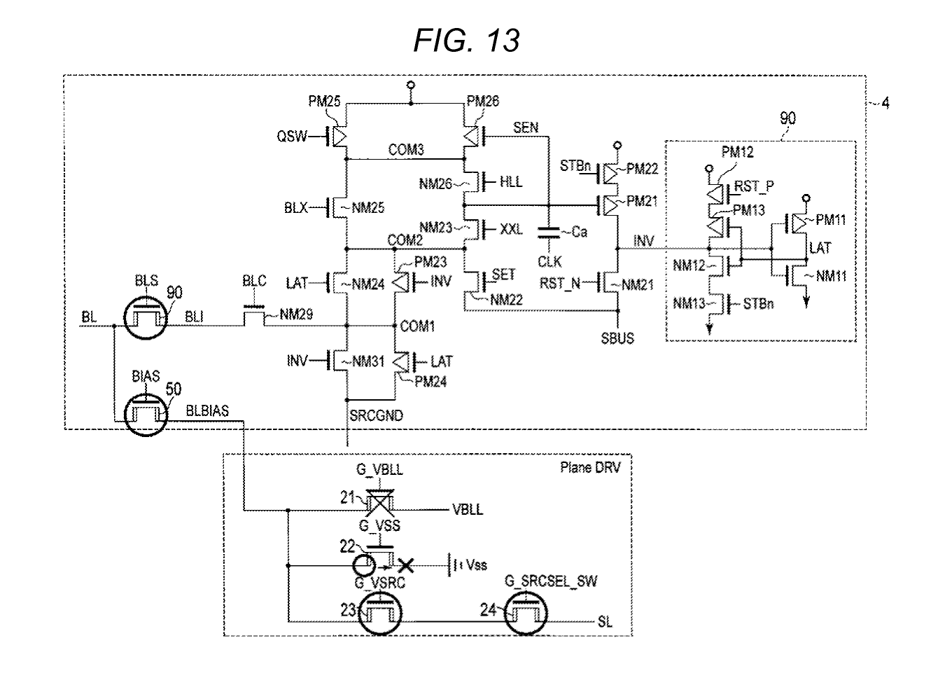

Hereinafter, a timing chart of the voltage of the bit line BL during the write operation according to the first embodiment will be described with reference to FIGS. 12 and 13.

FIG. 12 is a timing chart illustrating various voltages during the write operation according to the first embodiment. FIG. 13 is a circuit diagram of the sense amplifier 4 which is connected to the bit line in the nonvolatile semiconductor memory device according to the first embodiment that illustrates operations during the equalizing period (times t6 to t7 in FIG. 12) of the write operation.

Here, a voltage which is applied to the write bit line BL (program) and the write inhibition bit line BL (inhibit) will be described. Meanwhile, the voltage which is applied to the write bit line BL (program) and the write inhibition bit line BL (inhibit) is independently controlled by the sense amplifier 4 which is connected to each of the write bit line BL (program) and the write inhibition bit line BL (inhibit). In addition, a common voltage is applied to each of the sense amplifier 4 which is connected to the write bit line BL (program) and the sense amplifier 4 which is connected to the write inhibition bit line BL (inhibit) as various signals (signals BIAS, BLC, and BLS) shown in FIG. 12. In addition, the voltages Vss, Vbll, Vblinhibit, Vsl, and Vboostedlevel have the relationship of Vss<Vbll<Vblinhibit<Vsl<Vboostedlevel or the relationship of Vss<Vbll<Vsl<Vblinhibit<Vboostedlevel.

As shown in FIG. 12, first, as an initial state, a voltage Vt is applied as the signal BLC and a voltage VX4 is applied as the signal BLS. The voltage VX4 causes the transistor 50 to switch into an on state and has a sufficient size to transmit a voltage Vblinhibit which will be described later. In addition, the voltage Vss is applied as the other various voltages.

Subsequently, at a time t1, the voltage [Vblinhibit+Vt] is applied as the signal BLC. Therefore, the voltage Vblinhibit is applied from the power-supply voltage to the write inhibition bit line BL (inhibit). In addition, a voltage Vchpch is applied to the word line WL which is connected to the selected memory cell.

Subsequently, at a time t2, the voltage Vsl is applied to the source line SL. In addition, the voltage Vbll is applied to the write bit line BL (program) from a node VBLL through the node SRCGND. At this time, a sufficient voltage is applied as a signal G_VBLL and the transistor 21 is turned on, and thus the node BLBIAS is electrically connected to the node VBLL and the voltage Vbll is applied to the node BLBIAS. In addition, when the write bit line BL (program) is coupled to the source line SL, the voltage of the write inhibition bit line BL (inhibit) rises up to the voltage Vboostedlevel.

Subsequently, at a time t3, the voltage Vpass is applied to the word line WL which is connected to the selected memory cell. Meanwhile, although not shown in the drawing, at the time t3 or previous to the time t3, the voltage Vpass is applied to the word line WL which is connected to the non-selected memory cell.

Subsequently, at a time t4, the voltage Vpgm is applied to the word line WL which is connected to the selected memory cell. Therefore, a high electrical field is applied to the selected memory cell and data “0” is written. Meanwhile, although not shown in the drawing, at this time, the voltage Vpass is applied to the word line WL which is connected to the non-selected memory cell but the voltage Vpgm is not applied. Therefore, data “0” is not written in the non-selected memory cell. Thereafter, at a time t5, the voltage Vss is applied to the word line WL which is connected to the selected memory cell. At this time, for example, after the word line WL which is connected to the selected memory cell is discharged to Vpass, both the word lines WL which are connected to the selected and non-selected memory cells are discharged to Vss. Otherwise, for example, after the word line WL which is connected to the selected memory cell is discharged to Vss, the word line WL which is connected to the non-selected memory cell is discharged to Vss.

Subsequently, while the bit line BL (the write bit line BL (program) and the write inhibition bit line BL (inhibit)) are equalized with the source line SL, the voltages thereof drop. Hereinafter, an operation during the equalizing period of the bit line BL and the source line SL according to the first embodiment will be described.

First, at the time t6, a voltage VSS is applied as the signal BLC, and the voltage VX4 is applied as the signal BIAS. Therefore, the NMOS transistor NM29 is turned off, and the transistor 50 is turned on. In addition, sufficiently high voltages are applied as a signal G_VSRC and a signal G_VSRCSEL_SW, and thus the transistor 23 and the transistor 24 are turned on. Therefore, the bit line BL is equalized with the source line SL through the node BLBIAS.

At this time, as described above, during a period until the transistor 50 is turned on, the write inhibition bit line BL (inhibit) becomes a floating state. In this state, if the voltage of the write bit line BL (program) rises due to the equalization with the source line SL, the voltage of the write inhibition bit line BL (inhibit) rises due to the coupling with the write bit line BL (program). Therefore, there is a case in which the voltage of a node BLI rises to exceed the pressure resistance limit of the NMOS transistor NM29.

Accordingly, in the first embodiment, during the period until the transistor 50 which is connected to the write inhibition bit line BL (inhibit) is turned on (during the period that the write inhibition bit line BL (inhibit) is in the floating state), the voltage of the node BLBIAS temporarily drops to the voltage Vss. More specifically, a sufficiently high voltage is applied as a signal G_VSS, and the transistor 22 is turned on. Therefore, the node BLBIAS is connected to the ground voltage (voltage Vss). Meanwhile, it is preferable that a period that the node BLBIAS is connected to the voltage Vss be the period that the write inhibition bit line BL (inhibit) is in the floating state while the write bit line BL (program) is being equalized with the source line SL, i.e., the period during which the transistor 50 which is connected to the write inhibition bit line BL (inhibit) is turned off and the transistor 50 which is connected to the write bit line BL (program) is turned on.

When the voltage Vss is used as the voltage of the node BLBIAS, the voltages of the bit line BL (the write bit line BL (program) and the write inhibition bit line BL (inhibit)) and the source line SL which are electrically connected to the node BLBIAS temporarily drop. Therefore, it is possible to prevent the write inhibition bit line BL (inhibit) from rising above the voltage Vboostedlevel.

At this time, the transistor 22 may be turned on, for example, for a single clock cycle. That is, for example, a high voltage is applied as the signal G_VSS for a single clock cycle.

Thereafter, the voltage Vss is applied as the signal G_VSS and the transistor 22 is turned off. Therefore, the voltages of the write bit line BL (program), the write inhibition bit line BL (inhibit), and the source line SL temporarily rise. However, since the voltage of the write inhibition bit line BL (inhibit) drops once, the voltage of the write inhibition bit line BL (inhibit) does not rise above the voltage Vboostedlevel.

Thereafter, the various voltages drop until the time t7 and become the voltage Vss. Meanwhile, the voltage VX4 is applied as the signal BLS without change.

In this manner, the write operation according to the first embodiment ends.

### Advantages According to First Embodiment

According to the first embodiment, during the write operation, when the bit line BL (the write bit line BL (program) and the write inhibition bit line BL (inhibit)) are equalized with the source line SL through the node BLBIAS, the node BLBIAS is temporarily connected to the ground voltage (voltage Vss). Therefore, it is possible to suppress the voltage of the bit line BL (in particular, the write inhibition bit line BL (inhibit)) from rising through the node BLBIAS. Therefore, it is possible to suppress the voltage of the node BLI, which is connected to the other end of the current path of the NMOS transistor NM29, from rising and exceeding the pressure resistance limit of the NMOS transistor NM29.

The above effects are particularly effective for the BiCS memory rather than a normal planar NAND memory. The reason for this is shown below.

As shown in FIG. 10, in the BiCS memory, the threshold voltage of the drain side selection transistor SDTr is negative. Therefore, when the voltage Vss is simply applied to the drain side selection gate SGD of the non-selected memory string (memory string 40b), the drain side selection transistor SDTr is turned on. In contrast, when a comparatively high voltage Vbll is applied to the write bit line BL (program), it is possible to cause the threshold of the drain side selection transistor SDTr to be positive in a pseudo manner and thus it is possible to turn off the drain side selection transistor SDTr.

Further, as shown in FIG. 11, since the selected memory string (memory string 40c) is commonly connected to the selected memory string (memory string 40a) which is connected to the write bit line BL (program), the voltage Vsgd is applied to the drain side selection gate SGD of the selected memory string (memory string 40c) which is connected to the write inhibition bit line BL (inhibit). Therefore, it is necessary to apply the further higher voltage Vboostedlevel in order to turn off the drain side selection gate SGD of the memory string 40c. The voltage Vboostedlevel is greater than a voltage which is applied to a normal planar NAND bit line, and has a value which is close to the pressure resistance limit of the NMOS transistor NM29. Therefore, when the voltage Vboostedlevel further rises due to the coupling or the like, there is a possibility that the voltage Vboostedlevel will exceed the pressure resistance limit of the NMOS transistor NM29.

As described above, the exceeding of the pressure resistance limit of the NMOS transistor NM29 of the sense amplifier 4 may occur in the BiCS memory rather than the planar NAND. Therefore, the first embodiment is particularly effective in the BiCS memory in which the bit line BL voltage is further high.

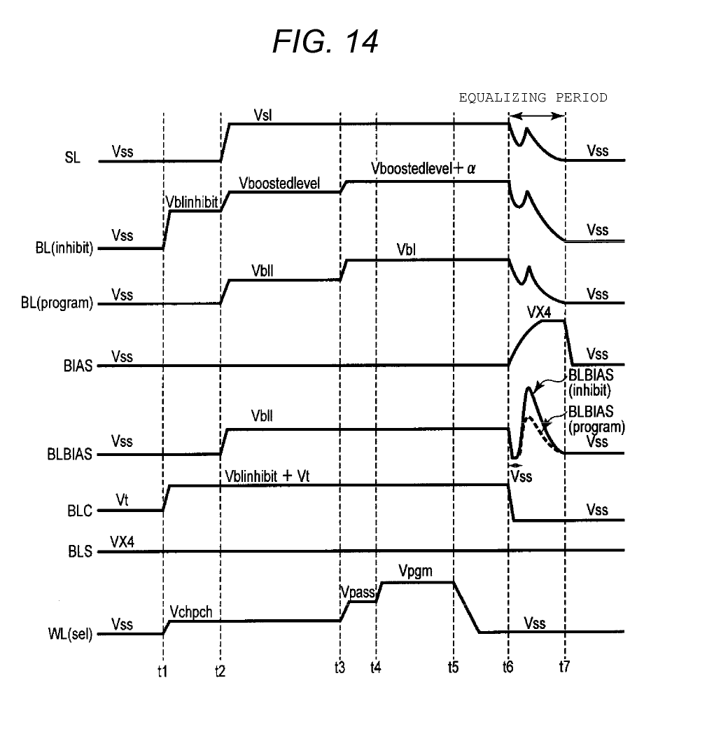

In addition, the first embodiment is effective in a first modification example below. FIG. 14 is a timing chart illustrating various voltages during a write operation according to the first modification example.

The first modification example shows a so-called Quick Pass Write (QPW) operation which is proposed to enable increase in a write time to be suppressed and the distribution width of the threshold voltage obtained after the write is performed to be further narrowed. The QPW operation is a method of performing write on an incomplete write memory cell by applying a voltage Vbl (Vbl>Vbll) to the bit line BL which is connected to the memory cell. Therefore, a channel region is charged with the voltage Vbl and a comparatively low electrical field is applied to the memory cell. As a result, it is possible to cause the distribution width of the threshold voltage of the memory cell to be small.

More specifically, as shown in FIG. 14, first, at times t1 and t2, the same operation as that of the first embodiment is performed. That is, the voltage Vbl is applied to the write bit line BL (program) and the voltage of the write inhibition bit line BL (inhibit) rises to a voltage Vboostedlevel.

Subsequently, at a time t3, the voltage Vbl is applied to the write bit line BL (program). The voltage Vbl is transmitted from the power-supply voltage. In addition, due to the coupling with the write bit line BL (program), the voltage of the write inhibition bit line BL (inhibit) rises to a voltage [Vboostedlevel+α (α is positive)].

Thereafter, during times t4 to t7, the same operation as that of the first embodiment is performed. That is, the same operation as that of the first embodiment is performed during an equalizing period between the bit line BL and the source line SL.

When the voltage Vss is used as the voltage of the node BLBIAS during the equalizing period, the voltages of the bit line BL (the write bit line BL (program) and the write inhibition bit line BL (inhibit)) and the source line SL which are electrically connected to the node BLBIAS temporarily drop. Therefore, it is possible that the voltage of the write inhibition bit line BL (inhibit) rises above the voltage [Vboostedlevel+α].

The voltage [Vboostedlevel+α] is a value which is closer to the pressure resistance limit of the NMOS transistor NM29. That is, in the QPW operation in which the bit line BL voltage becomes further higher as in the first modification example, the first embodiment is further effective.

### Second Embodiment

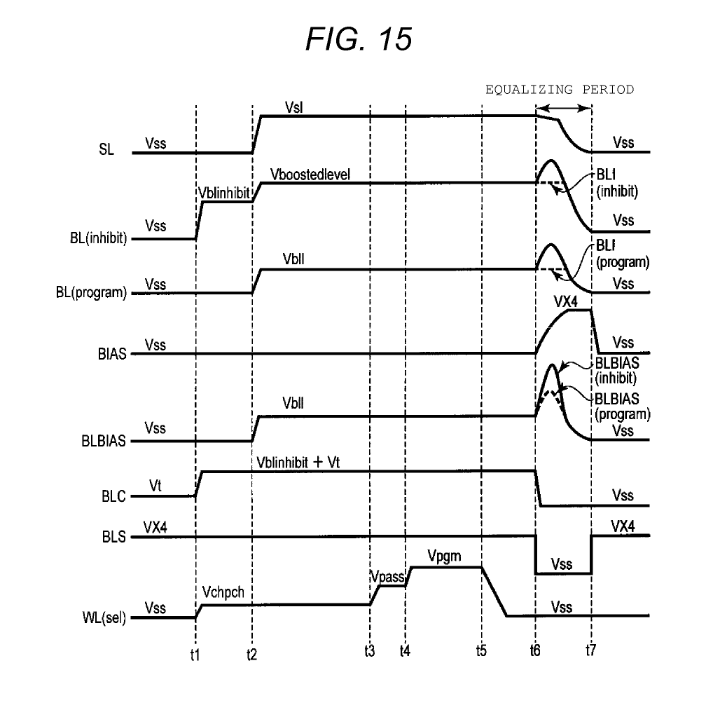

A nonvolatile semiconductor memory device according to a second embodiment will be described with reference to FIGS. 15 to 17. In the second embodiment, when the bit line BL (the write bit line BL (program) and the write inhibition bit line BL (inhibit)) are equalized with the source line SL through the node BLBIAS, the high pressure-resistant transistor 90 which is positioned between the bit line BL and the NMOS transistor NM29 is turned off. Therefore, it is possible to suppress the voltage of the node BLI (the other end of the current path of the NMOS transistor NM29) from rising and it is possible to prevent the pressure resistance limit of the NMOS transistor NM29 to be exceeded. Hereinafter, the nonvolatile semiconductor memory device according to the second embodiment will be described.

Meanwhile, in the second embodiment, the same features as in the first embodiment are not repeatedly described and different features are mainly described.

### Timing Chart of Voltage of Bit Line BL in Write Operation

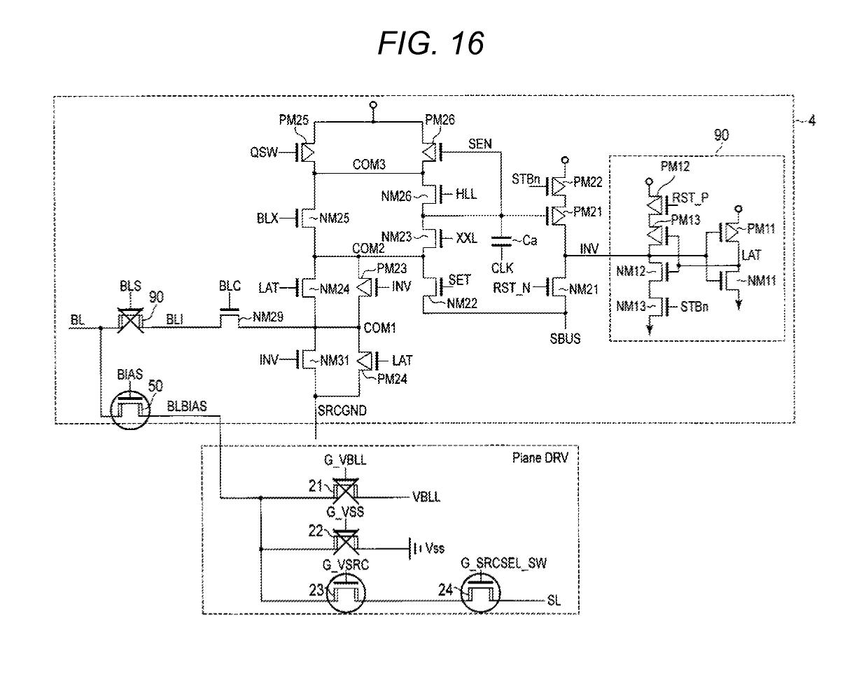

Hereinafter, a timing chart of the voltage of the bit line BL during the write operation according to the second embodiment will be described with reference to FIGS. 15 and 16.

FIG. 15 is a timing chart illustrating various voltages during the write operation according to the second embodiment. FIG. 16 is a circuit diagram of the sense amplifier 4 which is connected to the bit line according to the second embodiment that illustrates an operation during the equalizing period (times t6 to t7 in FIG. 15) during the write operation.

As shown in FIG. 15, first, during times t1 to t5, the same operation as that of the first embodiment is performed. That is, a high electrical field is applied to the selected memory cell, data “0” is written, and data “0” is not written in the non-selected memory cell. Thereafter, the voltage Vss is applied to the word line WL which is connected to the selected memory cell and the non-selected memory cell.

Subsequently, the bit line BL (the write bit line BL (program) and the write inhibition bit line BL (inhibit)) are equalized with the source line SL and the voltages thereof drop. Hereinafter, an operation during a period that the bit line BL is equalized with the source line SL according to the second embodiment will be described.

First, at the time t6, the voltage VSS is applied as the signal BLC, and the voltage VX4 is applied as the signal BIAS. Therefore, the NMOS transistor NM29 is turned off and the transistor 50 is turned on. In addition, a sufficiently high voltage is applied as the signal G_VSRC and the signal G_VSRCSEL_SW, and the transistor 23 and the transistor 24 are turned on. Therefore, the bit line BL is equalized with the source line SL through the node BLBIAS.

At this time, as described above, during the period until the transistor 50 is turned on, the write inhibition bit line BL (inhibit) becomes a floating state. In this state, if the voltage of the write bit line BL (program) rises due to the equalization with the source line SL, the voltage of the write inhibition bit line BL (inhibit) rises due to the coupling with the write bit line BL (program). Therefore, the voltage of the node BLI rises to exceed the pressure resistance limit of the NMOS transistor NM29 occurs.

In contrast, in the second embodiment, during the equalizing period (during that the voltages of the bit line BL and the source line SL drop), the high pressure-resistant transistor 90 is turned off. More specifically, the voltage Vss is applied as the signal BLS. That is, the node BLI (the other end of the current path of the NMOS transistor NM29) is not electrically connected to the bit line BL. Therefore, even when the voltage of the write inhibition bit line BL (inhibit) rises above the voltage Vboostedlevel due to the coupling with the write bit line BL (program), it is possible to prevent the voltage of the node BLI from rising above the voltage Vboostedlevel.

Meanwhile, the invention is not limited to where the transistor 90 is turned off by applying the voltage Vss as the signal BLS. The transistor 90 may be turned off to the extent that a voltage which is equal to or less than the pressure resistance limit of the NMOS transistor NM29 is transmitted to the node BLI. That is, a voltage which is higher than the voltage Vss may be applied as the signal BLS to the extent that the pressure resistance limit of the NMOS transistor NM29 is not exceeded.

In addition, although FIGS. 15 and 16 show the example that the voltage Vss is applied as the signal G_VSS at the time t6 and the transistor 22 is turned off, the invention is not limited thereto. As shown in the first embodiment, the voltage of the node BLBIAS may temporarily drop to the voltage Vss in such a way that, during the period that the write inhibition bit line BL (inhibit) is in the floating state, a sufficiently high voltage is temporarily applied as the signal G_VSS and the transistor 22 is turned on.

Thereafter, various voltages drop until the time t7 and become the voltage Vss. Meanwhile, the voltage VX4 is applied as the signal BLS without change.

In this manner, the write operation according to the second embodiment ends.

### Advantages According to Second Embodiment

According to the second embodiment, during the write operation, when the bit line BL (the write bit line BL (program) and the write inhibition bit line BL (inhibit)) are equalized with the source line SL through the node BLBIAS, the high pressure-resistant transistor 90 which is positioned between the bit line BL and the NMOS transistor NM29 is turned off. Therefore, the bit line BL is not electrically connected to the node BLI. Therefore, even when the voltage of the write inhibition bit line BL (inhibit) rises, it is possible to suppress the voltage of the node BLI (the other end of the current path of the NMOS transistor NM29) from rising and it is possible to prevent the pressure resistance limit of the NMOS transistor NM29 from being exceeded.

The advantage is particularly effective in the BiCS memory rather than a normal planar NAND memory.

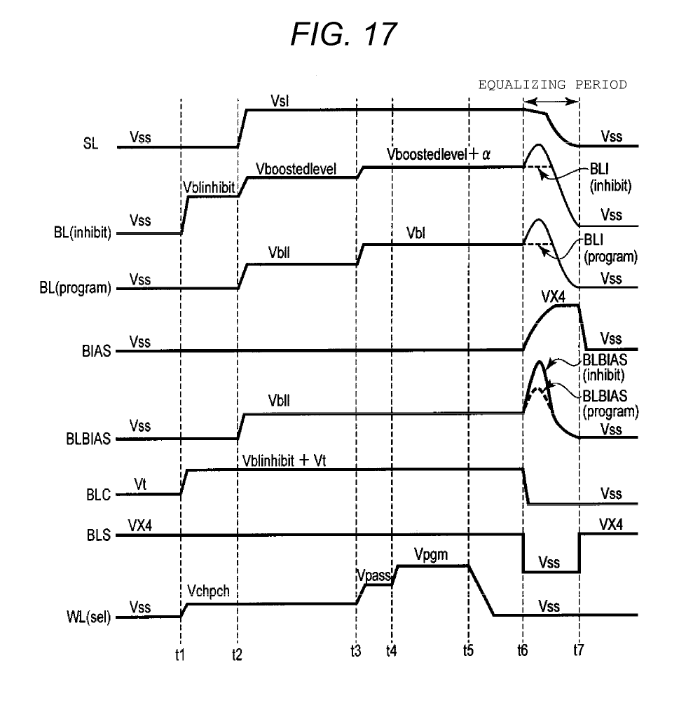

In addition, the second embodiment is effective in a second modification example below. FIG. 17 is a timing chart illustrating various voltages during the write operation according to the second modification example.

The second modification example shows a QPW operation proposed to suppress a write time from increasing and to enable the distribution width of the threshold voltage obtained after the write is performed to be narrowed.

More specifically, as shown in FIG. 17, first, at times t1 and t2, the same operation as that of the second embodiment is performed. That is, the voltage Vbl is applied to the write bit line BL (program) and the voltage of the write inhibition bit line BL (inhibit) rises to the voltage Vboostedlevel.

Subsequently, at a time t3, the voltage Vbl is applied to the write bit line BL (program). The voltage Vbl is transmitted from the power-supply voltage. In addition, the voltage of the write inhibition bit line BL (inhibit) rises to the voltage [Vboostedlevel+α (α is positive)] due to the coupling with the write bit line BL (program).

Thereafter, during times t4 to t7, the same operation as that of the second embodiment is performed. That is, the same operation as that of the second embodiment is performed even during the equalizing period between the bit line BL and the source line SL.

In the equalizing period, when a high pressure-resistant transistor 90 is turned off, the node BLI (the other end of the current path of the NMOS transistor NM29) is not electrically connected to the bit line BL. Therefore, even when the voltage of the write inhibition bit line BL (inhibit) rises above the voltage [Vboostedlevel+α] due to the coupling with the write bit line BL (program), it is possible to prevent the node BLI from rising above the voltage [Vboostedlevel+α].

The voltage [Vboostedlevel+α] is a value which is closer to the pressure resistance limit of the NMOS transistor NM29. That is, the second embodiment is further effective in the QPW operation in which the bit line BL voltage becomes further high as in the second modification example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a memory cell;
a bit line electrically connected to the memory cell;
a sense amplifier that includes a first transistor having a first end electrically connected to the bit line;
a second transistor electrically connected between a second end of the first transistor and ground;
a third transistor electrically connected between a second end of the first transistor and a source line; and
a controller configured to control the first, second, and third transistors after performing a program operation, wherein after the program operation,
the first and second transistors are turned on and then while the first transistor remains turned on, the second transistor is turned off and the third transistor is turned on.

2. The nonvolatile semiconductor memory device according to claim 1, wherein the first and second transistors are turned on at the same time after the program operation.

3. The nonvolatile semiconductor memory device according to claim 1, further comprising:
a high pressure-resistant transistor connected between the third transistor and the source line,
wherein the high pressure-resistant transistor is turned on when the third transistor is turned on.

4. The nonvolatile semiconductor memory device according to claim 1, wherein the sense amplifier further includes a fourth transistor that is turned on during the program operation and is turned off after the program operation.

5. The nonvolatile semiconductor memory device according to claim 4,
wherein the first transistor is a higher pressure-resistant transistor than the fourth transistor.

6. The nonvolatile semiconductor memory device according to claim 1, wherein a voltage level of the bit line at the end of the program operation is lower than a voltage level of the source line at the end of the program operation.

7. The nonvolatile semiconductor memory device according to claim 1, wherein a voltage level of the bit line at the end of the program operation is higher than a voltage level of the source line at the end of the program operation.

8. The nonvolatile semiconductor memory device according to claim 6, wherein the voltage level of the bit line at the end of the program operation is not exceeded after the program operation while the first transistor is turned on.

9. A nonvolatile semiconductor memory device comprising:
first and second memory strings each including a plurality of memory cells;
a first bit line that is electrically connected to a first end of the first memory string;
a second bit line that is electrically connected to a first end of the second memory string;
a source line that is electrically connected to second ends of the first and second memory strings;
a first sense amplifier that includes a first transistor having a first end electrically connected to the first bit line, a second transistor having a first end electrically connected to the first bit line and the first end of the first transistor, and a third transistor having a first end electrically connected to a second end of the second transistor; and
a second sense amplifier that includes a fourth transistor having a first end electrically connected to the second bit line, a fifth transistor having a first end electrically connected to the second bit line and the first end of the fourth transistor, and a sixth transistor having a first end electrically connected to a second end of the fifth transistor,
wherein, during a write operation, after a first voltage is applied to the first bit line, a second voltage which is higher than the first voltage is applied to the second bit line, and a third voltage which is higher than the first voltage and lower than the second voltage is applied to the source line, and then, after the write operation, the first and fourth transistors are turned on and second ends of the first and fourth transistors are connected to a ground voltage, and the third and sixth transistors are turned off.

10. The nonvolatile semiconductor memory device according to claim 9,
wherein, after the write operation and after the second ends of the first and fourth transistors have been connected to a ground voltage, the first and second bit lines are electrically connected to the source line.

11. The nonvolatile semiconductor memory device according to claim 9, further comprising:
a seventh transistor that controls the connection between the second end of the first transistor and the ground voltage; and
an eighth transistor that controls the connection between the second end of the fourth transistor and the ground voltage.

12. The nonvolatile semiconductor memory device according to claim 11, further comprising:
ninth and tenth transistors that control the connection between the second end of the first transistor and the source line; and
eleventh and twelfth transistors that control the connection between the second end of the fourth transistor and the source line.

13. The nonvolatile semiconductor memory device according to claim 12, wherein the tenth and twelfth transistors are high pressure resistant transistors.

14. The nonvolatile semiconductor memory device according to claim 9,
wherein the first, second, fourth, and fifth transistors are higher pressure-resistant transistors rather than the third and sixth transistors.

15. A method of performing an operation in a nonvolatile semiconductor memory device including a memory cell, a bit line electrically connected to the memory cell, a sense amplifier that includes a first transistor having a first end electrically connected to the bit line, a second transistor electrically connected between a second end of the first transistor and ground, and a third transistor electrically connected between a second end of the first transistor and a source line, said method comprising:
performing a program operation;
upon completion of the write operation, turning on the first and second transistors; and then
while the first transistor remains turned on, turning off the second transistor and turning on the third transistor.

16. The method according to claim 15, wherein the first and second transistors are turned on at the same time after the program operation.

17. The method according to claim 15, wherein the nonvolatile semiconductor memory device further includes a high pressure-resistant transistor connected between the third transistor and the source line, and the high pressure-resistant transistor is turned on when the third transistor is turned on.

18. The method according to claim 15, wherein the sense amplifier further includes a fourth transistor that is turned on during the program operation and is turned off after the program operation.

19. The method according to claim 15, wherein a voltage level of the bit line at the end of the program operation is lower than a voltage level of the source line at the end of the program operation.

20. The method according to claim 15, wherein a voltage level of the bit line at the end of the program operation is higher than a voltage level of the source line at the end of the program operation.
